(19) United States
(12) Patent Application Publication
(10) Pub. No.: US 2010/0068651 A1
(43) Pub. Date: Mar. 18, 2010

(54) DEVELOPING SOLUTION FOR FLEXOGRAPHIC PRINTING PLATES

(76) Inventor: David C. Bradford, Winston-Salem, NC (US)

Correspondence Address: EASTMAN KODAK COMPANY;PATENT LEGAL STAFF, 343 STATE STREET, ROCHESTER, NY, 14650-2201, US

(21) Appl. No.: 12/545,268

(22) Filed: Aug. 21, 2009

Related U.S. Application Data
(60) Provisional application No. 61/097,358, filed on Sep. 16, 2008.

(51) Int. Cl. G03F 7/20

(52) U.S. Cl. 430/306; 430/331

(57) ABSTRACT

A developing or processing solution can be used to provide flexographic relief printing plates. This processing solution comprises dipropylene glycol dimethyl ether (DME) and optionally one or more alcohols or other co-solvents. The processing solution is used to remove non-polymerized material after imaging while leaving polymerized material in a relief image.

### CROSS-REFERENCE TO RELATED APPLICATIONS

This application claims the benefit of U.S. Provisional Patent Application No. 61/097,358, filed Sep. 16, 2008, which is incorporated herein by reference in its entirety.

### FIELD OF THE INVENTION

The present invention relates to an improved processing solution (developer) and process for the production of flexographic printing plates crosslinked by photopolymerization. More specifically, the invention relates to a processing solution containing dipropylene glycol dimethyl ether (DME), alone or in combination with non-alcohol co-solvents or alcohols and to its use as a washout solvent for the non-polymerized material in the printing plates to provide a relief image.

### BACKGROUND OF THE INVENTION

Washout processes for the development of photopolymerizable flexographic printing plates are well known and is described in detail in U.S. Pat. No. 5,240,815 (Telser et al.). An essential step to any photopolymerizable relief printing process is the development of the printing plate after the image is formed through imagewise exposure of the photopolymerizable plate to suitable imaging radiation. The image is formed by polymerizing and crosslinking of the photopolymerizable material that is exposed while the unexposed portion remains non-polymerized. Ordinarily, development is accomplished by washing the exposed plate in a processing solution that can remove the non-polymerized material while leaving the polymerized (cured) material intact. Since such plates can be formed from a variety of materials, it is necessary to match a specific printing plate material with an appropriate developing solution.

For example, U.S. Pat. No. 4,323,636 (Chen), U.S. Pat. No. 4,323,637 (Chen et al.), U.S. Pat. No. 4,423,135 (Chen et al.), and U.S. Pat. No. 4,369,246 (Chen et al.) described a variety of photopolymer printing plate compositions based on block copolymers of styrene with butadiene (SBS) or isoprene (SIS). These compositions can be utilized to produce flexographic printing plates that can be developed using a number of aliphatic and aromatic solvents, including methyl ethyl ketone, toluene, xylene, d-limonene, carbon tetrachloride, trichloroethane, methyl chloroform, and tetrachloroethylene. These solvents may be used alone or in a mixture with other co-solvents such as alcohols, for example, a mixture of trichloroethane with ethanol. In any case, during the development step, the processing solution can be applied in any convenient manner such as by pouring, immersing, spraying, or roller application. Brushing, which aids in the removal of the non-polymerized or uncrosslinked portions of the composition, can also be used to facilitate the processing of the plate.

There is a continuing need to provide environmentally friendly developing solutions that are effective for providing relief images, for example in flexographic printing plates.

### SUMMARY OF THE INVENTION

The present invention provides a developing solution for providing a flexographic relief printing plate, the developing solution comprising dipropylene glycol dimethyl ether (DME) alone or with one or more co-solvents.

This invention also provides a method for preparing a flexographic relief printing plate comprising:

processing an exposed (or imaged) flexographic relief printing plate precursor with an organic developing solution comprising dipropylene glycol dimethyl ether (DME) to remove non-polymerized photopolymerizable material.

The developing solutions of this invention, which comprise dipropylene glycol dimethyl ether (DME) either alone or in the presence of other organic co-solvents, can be used to process a variety of photopolymerizable polymeric compositions (that is, remove the non-polymerized polymerizable material), including, but is not limited to SBS and SIS polymer systems, as well as a large number of nitrile rubber and other copolymer systems. DME provides a unique combination of advantages including reduced cost, improved plate quality, low volatility, improved regulatory compliance, low toxicity, reduced washout time, and biodegradability.

It is, therefore, an object of the present invention to provide a processing solution and a process for the preparation of relief flexographic printing plates crosslinked by photopolymerization, in which the washout time and the drying time are substantially shorter compared with the conventional processing solutions, and wherein the relief plates suffer neither excessive surface swelling nor under-washing and are characterized by improved relief depths and sidewall structure.

Another object of the present invention is to provide a process for the preparation of relief flexographic printing plates crosslinked by photopolymerization that is capable of operation without expensive explosion-prevention protection.

It is another object of the present invention to provide processing solutions for use with photopolymerable printing plates that avoid the spontaneous combustion problems of the prior art solutions.

It is still another object of the present invention is to provide processing solutions that minimize workplace hazards and require minimal regulatory reporting.

### DETAILED DESCRIPTION OF THE INVENTION

The present invention is directed to a processing solution comprising dipropylene glycol dimethyl ether (DME) for use in photopolymer printing plate processing. DME can be used either alone or in a blended form with one or more non-alcohol co-solvents, one or more alcohol co-solvents, or one or more of both types of co-solvents.

Suitable alcohols include, but is not limited to, n-butanol, 2-ethoxyethanol, benzyl alcohol, ethanol, methanol, propanol, isopropanol, a hexyl alcohol, a heptyl alcohol, an octyl alcohol, a nonyl alcohol, a decyl alcohol, alpha-terpineol, dipropylene glycol methyl ether, 2-butoxyethanol, isopropyl alcohol, 2-(2-butoxyethoxy)ethanol, substituted or unsubstituted cyclopentanol, substituted or unsubstituted cyclohexanol, substituted or unsubstituted cycloheptanol, cyclopentyl substituted alcohol, cyclohexyl substituted alcohol, and cycloheptyl substituted alcohol. Mixtures of these alcohols as well as mixtures of these with other alcohols that are not listed here can also be used.

Some particularly useful alcohols include the one or more of 4-ethylcyclohexanol, 2,3-dimethylcyclopentanol, cyclohexylpropanol, and 4-cyclopentylpentanol.

The non-alcohol co-solvents should be miscible with the DME and the alcohols, should have acceptable toxicity and safety profiles, and should be readily disposable or recyclable. Low cost and recyclability is highly desirable in a co-solvent. Suitable co-solvents include, but are not limited to, dimethyl-2-methyl glutarate; diisopropylbenzene; and petroleum distillates, such as aliphatic petroleum distillates, naphthas, paraffinic solvents (such as isoparaffinic solvents), hydrotreated petroleum distillates, mineral oil, mineral spirits, ligroin, decane, octane, hexane; and other similar materials. Mixtures of these non-alcohol co-solvents as well as mixtures of these with other co-solvents that are not listed here can also be used. Isoparaffinic solvents are commercially available in a wide range of volatility and corresponding flash points. The developing solution of the invention can made with commercially available isoparaffinic solvents as its co-solvent base.

The use of isoparaffinic solvents as the co-solvents has other benefits over that of traditional aliphatic or naphthinic distillates in the same boiling ranges. The benefits include:

(1) Less energy is used when drying the printing plates. Also, less energy is used to distill or reclaim the solvent for reuse. The isoparaffinic solvents normally have lower latent heats of vaporization;

(2) Isoparaffinic solvents exhibit less swelling of rubber or elastomer seals and hosing;

(3) Isoparaffinic solvents exhibit lower odor characteristics than the odor characteristics of traditional aliphatic distillates; and

(4) Isoparaffinic solvents, with purity approaching that of U.S.P. White Oil, are less irritating to the skin than traditional aliphatic solvents.

Parameters such as drying rates, fire risk, workplace air quality, and volatile organic compound emissions will also play a role in the choice of co-solvent.

Other minor components, such as defoamers and stabilizers may also be added to the developer solution of this invention. These minor components should be no more than about 0.05% by volume of the total solution composition.

The developing solution components can be varied but a suitable composition contains from about 5 to about 75% by volume of DME (typically from about 5 to about 50%, or from about 15 to about 40%); and from about 18 to about 27% by volume of an alcohol or mixture of alcohols.

A useful processing solution contains DME, benzyl alcohol, dimethyl-2-methyl glutarate, and isoparaffinic solvents. Another useful processing solution contains from about 15 to about 40% by volume of DME, from about 18 to about 27% of benzyl alcohol, from about 5 to about 40% of dimethyl-2-methyl glutarate, and the remaining balance of solvents are isoparaffinic solvents. Yet another useful processing solution contains about 28% by volume of DME, about 20% by volume of benzyl alcohol, about 10% of dimethyl-2-methyl glutarate, and about 42% isoparaffinic solvents.

The DME-based processing solutions of this invention may be substituted for the synthetic hydrocarbon, oxygenated solvents or halogenated hydrocarbon solvents known for processing photopolymer printing plates. For example, the DME-based processing solutions are suitable in the processing of photopolymer printing plates based on block copolymers of styrene and butadiene (SBS), block copolymers of styrene and isoprene (SIS), copolymers of butadiene and acrylonitrile, terpolymers of butadiene, acrylonitrile, and acrylic acid, and other similar photopolymers. The DME-based processing solutions can be applied to the imaged flexographic printing plate precursors by any conventional application means including spraying, brushing, rolling, dipping (immersing), or any combination thereof. The DME-based solutions can also be used to produce flexographic printing plates with less cured polymer image swelling than those processed in conventional hydrocarbon or chlorinated hydrocarbon solvents. Since swelling tends to distort the image formed, this surprising result permits clear, sharper images to be formed at much lower exposure times than those resulting from the use of conventional solutions.

The following Example is provided to illustrate the practice of this invention but the invention is not to be interpreted as limited by these Examples.

### EXAMPLE

A commercially available 0.067″ thick flexographic printing plate precursor (Kodak Flexcel® SRH) was first exposed from the back using a UV light source (Concept 305 EDLF, available from Mekrom Inc, Delaware, USA) to form the cross-linked polymer floor of the printing plate. The back exposure time was about 20 seconds, enough to give a floor thickness of 0.034 inch. Next, the top of the plate precursor was exposed (imaged) through a negative mask for 10 minutes by the same UV light source as above. The exposed plate precursor was then developed using a Concept 305 P processor available from Mekrom at a speed of 3.5 inches per minute using a developer composition comprising 23% (volume) dipropylene glycol dimethyl ether (DME), 17% of dimethy-2-methyl glutarate, 37% of a petroleum distillate (Isopar M, available from Exxon Mobil), and 23% of benzyl alcohol. The developed flexographic printing plate was then dried in the drier unit of the Concept 305 EDLF equipment for 75 minutes at 60° C. After drying the printing plate was then post exposed for 10 minutes, and finished (detacking) by using UVC for 10 minutes. The finished flexographic printing plate showed good image quality when examined under a 60× microscope.

The invention has been described in detail with particular reference to certain preferred embodiments thereof, but it will be understood that variations and modifications can be effected within the spirit and scope of the invention.

1. A method for preparing a flexographic relief printing plate comprising:
processing an exposed flexographic relief printing plate precursor with an organic processing solution comprising dipropylene glycol dimethyl ether (DME) to remove non-polymerized photopolymerizable material.

2. The method of claim 1 wherein the non-polymerized photopolymerizable material comprises one or more block co-polymers of styrene and butadiene, block co-polymers of styrene and isoprene, co-polymers of butadiene and acrylonitrile, or terpolymers of butadiene, acrylonitrile, and acrylic acid.

3. The method of claim 1 wherein the processing solution further comprises one or more alcohols.

4. The method of claim 3 wherein the processing solution comprises one or more of n-butanol, 2-ethoxyethanol, benzyl alcohol, ethanol, methanol, propanol, isopropanol, a hexyl alcohol, a heptyl alcohol, an octyl alcohol, a nonyl alcohol, a decyl alcohol, alpha terpineol, dipropylene glycol methyl ether, 2-butoxyethanol, isopropyl alcohol, 2-(2-butoxyethoxy)ethanol, substituted or unsubstituted cyclopentanol, substituted or unsubstituted cyclohexanol, substituted or unsubstituted cycloheptanol, cyclopentyl substituted alcohol, cyclohexyl substituted alcohol, or cycloheptyl substituted alcohol.

5. The method of claim 3 wherein the one or more alcohols includes one or more of 4-ethylcyclohexanol, 2,3-dimethylcyclopentanol, cyclohexylpropanol, or 4-cyclopentylpentanol.

6. The method of claim 1 wherein the processing solution further comprises one or more non-alcohol co-solvents.

7. The method of claim 6 wherein the one or more non-alcohol co-solvents are selected from the group consisting of dimethyl-2-methyl glutarate, diisopropylbenzene, aliphatic petroleum distillates, naphthas, paraffinic solvents, hydro-treated petroleum distillates, mineral oil, mineral spirits, ligroin, decane, octane, and hexane.

8. The method of claim 1 wherein the processing solution further comprises one or more alcohols and one or more non-alcohol co-solvents.

9. The method of claim 8 wherein the one or more alcohols include n-butanol, 2-ethoxyethanol, benzyl alcohol, ethanol, methanol, propanol, isopropanol, a hexyl alcohol, a heptyl alcohol, an octyl alcohol, a nonyl alcohol, a decyl alcohol, alpha terpineol, dipropylene glycol methyl ether, 2-butoxyethanol, isopropyl alcohol, 2-(2-butoxyethoxy)ethanol, substituted or unsubstituted cyclopentanol, substituted or unsubstituted cyclohexanol, substituted or unsubstituted cycloheptanol, cyclopentyl substituted alcohol, cyclohexyl substituted alcohol, and cycloheptyl substituted alcohol, and the one or more non-alcohol co-solvents are selected from the group consisting of dimethyl-2-methyl glutarate, diisopropylbenzene, aliphatic petroleum distillates, naphthas, paraffinic solvents, hydro-treated petroleum distillates, mineral oil, mineral spirits, ligroin, decane, octane, and hexane.

10. The method of claim 8 wherein the DME is present in the processing solution in an amount of from about 5 to about 75% by volume and the one or more alcohols are present in an amount of from about 18 to about 27% by volume.

11. The method of claim 1 comprising, before the processing step, imaging said flexographic relief printing plate precursor through a negative mask.

12. A processing solution for providing a flexographic relief printing plate, the processing solution comprising dipropylene glycol dimethyl ether (DME) alone or with one or more co-solvents.

13. The processing solution of claim 12 further comprising one or more alcohols.

14. The processing solution of claim 13 wherein the one or more alcohols include one or more of n-butanol, 2-ethoxyethanol, benzyl alcohol, ethanol, methanol, propanol, isopropanol, a hexyl alcohol, a heptyl alcohol, an octyl alcohol, a nonyl alcohol, a decyl alcohol, alpha terpineol, dipropylene glycol methyl ether, 2-butoxyethanol, isopropyl alcohol, 2-(2-butoxyethoxy)ethanol, substituted or unsubstituted cyclopentanol, substituted or unsubstituted cyclohexanol, substituted or unsubstituted cycloheptanol, cyclopentyl substituted alcohol, cyclohexyl substituted alcohol, or cycloheptyl substituted alcohol.

15. The processing solution of claim 13 wherein the one or more alcohols include one or more of 4-ethylcyclohexanol, 2,3-dimethylcyclopentanol, cyclohexylpropanol, or 4-cyclopentylpentanol.

16. The processing solution of claim 12 wherein the processing solution further comprises one or more non-alcohol co-solvents.

17. The processing solution of claim 16 wherein the one or more non-alcohol co-solvents are selected from the group consisting of dimethyl-2-methyl glutarate, diisopropylbenzene, aliphatic petroleum distillates, naphthas, paraffinic solvents, hydro-treated petroleum distillates, mineral oil, mineral spirits, ligroin, decane, octane, and hexane.

18. The processing solution of claim 12 further comprising one or more alcohols and one or more non-alcohol co-solvents.

19. The processing solution of claim 18 wherein the one or more alcohols include n-butanol, 2-ethoxyethanol, benzyl alcohol, ethanol, methanol, propanol, isopropanol, a hexyl alcohol, a heptyl alcohol, an octyl alcohol, a nonyl alcohol, a decyl alcohol, alpha terpineol, dipropylene glycol methyl ether, 2-butoxyethanol, isopropyl alcohol, 2-(2-butoxyethoxy)ethanol, substituted or unsubstituted cyclopentanol, substituted or unsubstituted cyclohexanol, substituted or unsubstituted cycloheptanol, cyclopentyl substituted alcohol, cyclohexyl substituted alcohol, and cycloheptyl substituted alcohol, and the one or more non-alcohol co-solvents are selected from the group consisting of dimethyl-2-methyl glutarate, diisopropylbenzene, aliphatic petroleum distillates, naphthas, paraffinic solvents, hydro-treated petroleum distillates, mineral oil, mineral spirits, ligroin, decane, octane, and hexane.

20. The processing solution of claim 18 wherein DME is present in an amount of from about 5 to about 75% by volume and the one or more alcohols are present in an amount of from about 18 to about 27% by volume.
